(19) United States
(12) Patent Application Publication
(10) Pub. No.: US 2025/0143097 A1
(43) Pub. Date: May 1, 2025

(54) DISPLAY DEVICE AND METHOD FOR FABRICATING THE SAME

(71) Applicant: Samsung Display Co., LTD., Yongin-si (KR)

(72) Inventors: Chaun Gi CHOI, Yongin-si (KR); Dong Uk KIM, Yongin-si (KR); Hyun Ho KIM, Yongin-si (KR); Hyoeng Ki KIM, Yongin-si (KR); Hyeon Bum LEE, Yongin-si (KR); Hoon Gi LEE, Yongin-si (KR)

(21) Appl. No.: 18/738,986

(22) Filed: Jun. 10, 2024

(30) Foreign Application Priority Data
Oct. 26, 2023 (KR) 10-2023-0144315

(51) Int. Cl. H10K 59/123; H10K 59/12; H10K 59/122; H10K 59/80

(52) U.S. Cl. CPC H10K 59/123; H10K 59/1201; H10K 59/122; H10K 59/873

(57) ABSTRACT

A display device includes: a substrate including a display area and a non-display area; a thin film transistor on the substrate; a planarization layer on the thin film transistor; a via layer on the planarization layer, having a recess in the display area and an alignment mark in the non-display area; a sub-pixel including a first electrode, an organic light emitting layer, and a second electrode corresponding to the recess; and a pixel definition layer defining the sub-pixel on the via layer, wherein the first electrode is electrically connected to the thin film transistor and includes an inclined electrode arranged along a sloped surface of the recess.

### CROSS-REFERENCE TO RELATED APPLICATION

The present application claims priority to and the benefit of Korean Patent Application No. 10-2023-0144315, filed on Oct. 26, 2023, in the Korean Intellectual Property Office, the entire disclosure of which is incorporated herein by reference.

### BACKGROUND

### 1. Field

Aspects of some embodiments of the present disclosure relate to a display device and a method of manufacturing the display device.

### 2. Description of the Related Art

Display devices are becoming increasingly important with the development of multimedia. In response to this, various types of display devices, such as liquid crystal displays (LCD) and organic light emitting displays (OLED), are being used.

Organic light emitting displays generally include an organic light emitting element that generates light by recombination of electrons and holes to display images. Organic light emitting display may have a relatively fast response time, relatively high brightness, and relatively good viewing angles, and may be driven with relatively low power consumption.

The above information disclosed in this Background section is only for enhancement of understanding of the background and therefore the information discussed in this Background section does not necessarily constitute prior art.

### SUMMARY

Aspects and features of some embodiments of the present disclosure include a display device that may prevent or reduce screen smudges and the like that may be caused by the inclined portion of the first electrode being covered by a pixel-defining layer.

However, the characteristics of embodiments according to the present disclosure are not restricted to those specifically described herein. The above and other features of embodiments according to the present disclosure will become more apparent to one of ordinary skill in the art to which the disclosure pertains by referencing the detailed description of the disclosure given below.

According to some embodiments of the present disclosure, a display device comprises a substrate including a display area and a non-display area, a thin film transistor on the substrate, a planarization layer on the thin film transistor, a via layer on the planarization layer, having a recess in the display area and an alignment mark in the non-display area, a sub-pixel including a first electrode, an organic light emitting layer, and a second electrode corresponding to the recess and a pixel definition layer defining the sub-pixel on the via layer, wherein the first electrode is electrically connected to the thin film transistor and includes an inclined electrode arranged along a sloped surface of the recess.

According to some embodiments, the first electrode further comprises a lower electrode extending from a bottom end of the inclined electrode and in the recess, and an upper electrode extending from a top end of the inclined electrode and on a top surface of the via layer.

According to some embodiments, the upper electrode comprises a concealed portion that overlaps the pixel defining layer and an exposed portion that does not overlap the pixel defining layer.

According to some embodiments, the exposed portion has a length of 1 μm to 2 μm.

According to some embodiments, the organic light emitting layer overlaps the lower electrode, the inclined electrode, and the upper electrode.

According to some embodiments, the pixel defining layer is in direct contact with a top surface of the via layer.

According to some embodiments, the alignment mark is made of the same material as the via layer.

According to some embodiments, the alignment mark is formed in an engraved pattern in which a portion of the top surface of the via layer is recessed.

According to some embodiments, the alignment mark comprises an ink that fills the engraved pattern, and the ink has a different color to the top surface of the via layer.

According to some embodiments, the display device further comprises a thin film encapsulation layer on the sub-pixel and the pixel defining layer.

According to some embodiments of the present disclosure, a method of manufacturing display device comprises forming a planarization layer on a substrate having a thin film transistor, forming an organic layer on the planarization layer, patterning the organic layer to form a via layer having a recess and an alignment mark, forming a first electrode electrically connected to the thin film transistor and including an inclined electrode arranged along a sloped surface of the recess and forming a pixel defining layer exposing at least a portion of the first electrode on the via layer using the alignment mark.

According to some embodiments, the method further comprises forming a lower electrode extending from a bottom end of the inclined electrode and in the recess, and an upper electrode extending from a top end of the inclined electrode and on a top surface of the via layer in forming the first electrode.

According to some embodiments, the method further comprises forming an organic light emitting layer on a first electrode exposed by the pixel defining layer and forming a second electrode on the organic light emitting layer.

According to some embodiments, the pixel defining layer exposes the lower electrode and the inclined electrode and overlaps at least a portion of the upper electrode.

According to some embodiments, the upper electrode comprises a concealed portion that overlaps the pixel defining layer and an exposed portion that does not overlap the pixel defining layer, wherein the exposed portion has a length of 1 μm to 2 μm.

According to some embodiments, the pixel defining layer is formed to be in direct contact with a top surface of the via layer.

According to some embodiments, the alignment mark is made of the same material as the via layer.

According to some embodiments, the alignment mark is formed in an engraved pattern in which a portion of the top surface of the via layer is recessed.

According to some embodiments, the alignment mark comprises an ink that fills the engraved pattern, wherein the ink has a different color to the top surface of the via layer.

According to some embodiments, the method further comprises forming a thin film encapsulation layer on the second electrode.

In a display device according to some embodiments of the present disclosure, misalignment of the pixel definition layer may be relatively reduced or minimized. Also, even if the pixel defining layer is misaligned, overlapping of the inclined electrode of the first electrode with the pixel defining layer may be prevented or reduced.

However, the characteristics of embodiments according to the present disclosure are not limited to the aforementioned characteristics, and various other characteristics are included in the specification.

### BRIEF DESCRIPTION OF THE DRAWINGS

The above and other amendments, characteristics, and features of embodiments according to the present disclosure will become more apparent by describing in more detail aspects of some embodiments thereof with reference to the attached drawings, in which:

FIG. 1 is a perspective view of a display device according to some embodiments.

FIG. 2 is a plan view of a display device according to some embodiments.

FIG. 3 is a cross-sectional view illustrating one example of a structure taken along the line I-I′ of FIG. 2.

FIG. 4 is a cross-sectional view illustrating one example of a structure of a sub-pixel included in a display device according to some embodiments of the present disclosure.

FIGS. 5A and 5B are cross-sectional views illustrating one example of an enlarged view of the area A of FIG. 4.

FIGS. 6 and 7 are cross-sectional views of a light emitting element and a pixel definition layer to illustrate alignment of the pixel definition layer according to some embodiments.

FIG. 8 is a schematic cross-sectional view of the structure of an alignment mark (AK) area according to some embodiments.

FIG. 9 is a plan view to illustrate the alignment mark of FIG. 8, according to some embodiments of the present disclosure.

FIG. 10 is a schematic diagram to illustrate the alignment mark of FIG. 9 according to some embodiments.

FIG. 11 is a plan view to illustrate the alignment marks according to some embodiments of the present disclosure.

FIGS. 12A and 12B are schematic diagrams to illustrate the alignment mark of FIG. 11 according to some embodiments.

FIGS. 13 to 17 are process flowcharts for manufacturing a display device according to some embodiments.

### DETAILED DESCRIPTION

Aspects of some embodiments will now be described more fully hereinafter with reference to the accompanying drawings. The embodiments may, however, be provided in different forms and should not be construed as limiting. The same reference numbers indicate the same components throughout the disclosure. In the accompanying drawing figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “belo”,” “eneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, althou”h th'terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein Is Inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

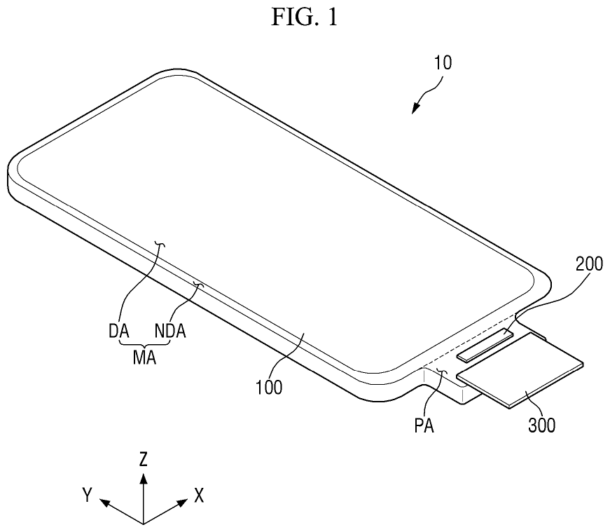

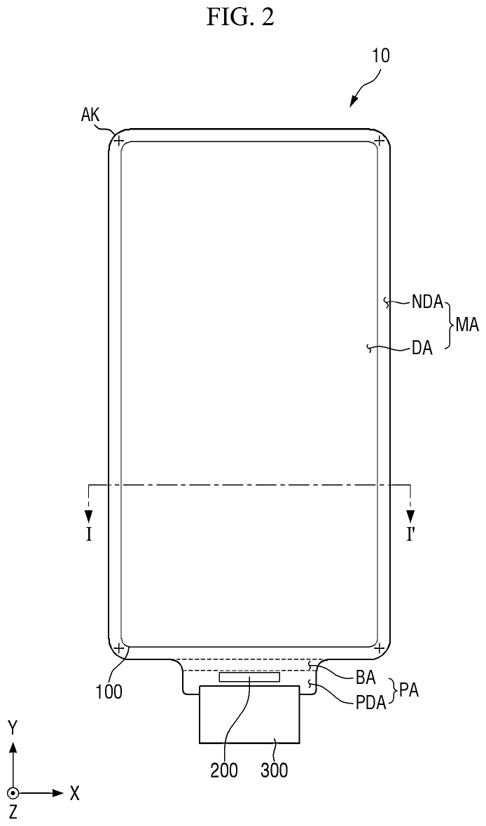

FIG. 1 is a perspective view of a display device according to some embodiments. FIG. 2 is a plan view of a display device according to some embodiments.

Referring to FIGS. 1 and 2, a display device 10 is a device for displaying video (e.g., moving images) or still images (e.g., static images), such as mobile phones, smart phones, tablet personal computers, and portable electronic devices such as smart watches, watch phones, mobile communication terminals, electronic notebooks, e-books, portable electronic devices such as portable multimedia players (PMP), navigation, and ultra mobile PCs (UMPC), as well as display screens for a variety of products such as televisions, laptops, monitors, billboards, and the internet of things (IoT). The display device 10 may be any one of an organic light emitting display device, a liquid crystal display device, a plasma display device, a field emitting display device, an electrophoretic display device, an electrowetting display device, a quantum dot light emitting display device, and a micro LED display device. In the following, the display device 10 is described with reference to the organic light emitting display device, but the present disclosure is not limited thereto.

The display device 10 according to some embodiments includes a display panel 100, a display driving circuit 200, and a circuit board 300.

The display panel 100 may include a main area MA and a protruding area PA protruding from one side of the main area MA.

The main area MA may be formed as a rectangular-shaped plane having a short side in a first direction (X-axis direction) and a long side in a second direction (Y-axis direction) that intersects the first direction (X-axis direction). A corner where the short side in the first direction (X-axis direction) and the long side in the second direction (Y-axis direction) meet may be rounded to have a curvature (e.g., a set or predetermined curvature) or may be formed at a right angle. The planar shape of the display device 10 is not limited to a rectangle, and may be formed in other polygonal, circular, or oval shapes. The main area MA may be formed flat but is not limited thereto and may include curved portions formed at left and right ends. In this case, the curved portion may have a constant curvature or a changing curvature.

The main area MA may include a display area DA in which pixels are formed to display images, and a non-display area NDA that is a surrounding area (e.g., in a periphery or outside a footprint) of the display area DA.

The display area DA may include a plurality of pixels, as well as scan lines, data lines, and power supply lines connecting to the pixels. When the main area MA includes a curved portion, the display area DA may be located on the curved portion. In this case, the image of the display panel 100 may be visible even on the curved portion.

The non-display area NDA may be defined as an area from the outside of the display area DA to the edge of the display panel 100. The non-display area NDA may include a scan driving portion for applying scan signals to the scan lines, and link lines connecting the data lines to the display driving circuit 200.

In the non-display area NDA of the display panel 100, an alignment mark AK may be formed that is necessary for processing the pixel definition layer. Although FIG. 2 shows four alignment marks AK, embodiments according to the present disclosure are not limited thereto. For example, according to various embodiments, the non-display area NDA may include additional alignment marks AK or fewer alignment marks AK without departing from the spirit and scope of embodiments according to the present disclosure. The shape and size of the alignment marks AK may be modified.

The protruding area PA may protrude from one side of the main area MA. For example, the protruding area PA may protrude from the lower side of the main area MA as shown in FIG. 2. A length of the protruding area PA in the first direction (X-axis direction) may be smaller than a length of the main area MA in the first direction (X-axis direction).

The protruding area PA may include a bending area BA and a pad area PDA. In this case, the pad area PDA may be located on one side of the bending area BA, and the main area MA may be located on the other side of the bending area BA. For example, the pad area PDA may be located below the bending area BA, and the main area MA may be located above the bending area BA.

The display panel 100 may be flexibly formed to be able to bend, flex, bend, fold, or curl. Therefore, the display panel 100 may be bent in the thickness direction (Z-axis direction) in the bending area BA. In this case, before the display panel 100 is bent, one side of the pad area PDA of the display panel 100 is facing upward, but after the display panel 100 is bent, one side of the pad area PDA of the display panel 100 is facing downward. As a result, the pad area PDA is located below the main area MA and may overlap with the main area MA.

The pad area PDA of the display panel 100 may include pads electrically connected to the display driving circuit 200 and the circuit board 300.

The display driving circuit 200 outputs signals and voltages for driving the display panel 100. For example, the display driving circuit 200 may supply data voltages to data lines. In addition, the display driving circuit 200 may supply power voltage to the power supply line and may supply scan control signals to the scan driving portion. The display driving circuit 200 may be formed as an integrated circuit (IC) and mounted on the display panel 100 in a chip on glass (COG), chip on plastic (COP), or ultrasonic bonding manner on the pad area PDA but is not limited to. For example, the display driving circuit 200 may be mounted on the circuit board 300.

The pads may IIe display pads “lect'lcally connected to the display driving circuit 200 and touch pads electrically connected to touch lines.

The circuit board 300 may be attached to the pads using an anisotropic conductive film. Thereby, the lead lines of the circuit board 300 may be electrically connected to the pads. The circuit board 300 may be a flexible film, such as a flexible printed circuit board, a printed circuit board, or a chip on film.

A touch driving circuit 400 may be connected to touch electrodes of a touch sensor layer TSL of the display panel 100. The touch driving circuit 400 applies driving signals to the touch electrodes of the touch sensor layer TSL and measures capacitance values of the touch electrodes. The driving signal may be a signal having a plurality of driving pulses. Based on the capacitance values, the touch driving circuit 400 may determine whether a touch has been input, as well as calculate touch coordinates where a touch has been input.

The touch driving circuit 400 may be located on the circuit board 300. The touch driving circuit 400 may be formed as an integrated circuit (IC) and mounted on the circuit board 300.

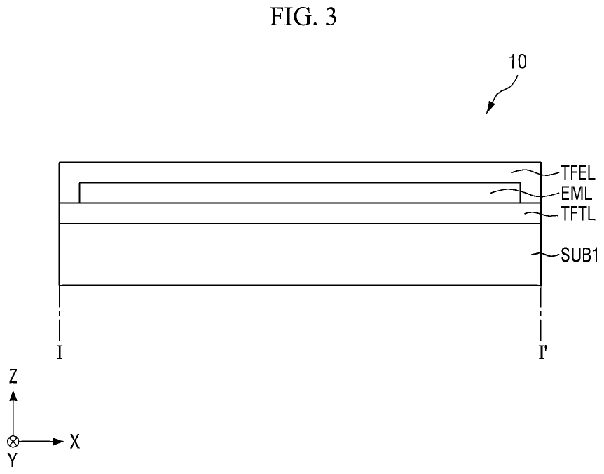

FIG. 3 is a cross-sectional view illustrating one example of a structure taken along the line I-I′ of FIG. 2.

Referring to FIG. 3, the display panel 100 may include a substrate SUB, a thin film transistor layer TFTL, a light emitting element layer EML, and a thin film encapsulation layer TFEL located on the substrate SUB.

The substrate SUB may be made of an insulating material such as glass, quartz, or polymer resin. Examples of polymer materials include polyethersulphone (PES), polyacrylate (PA), polyarylate (PAR), polyetherimide (PEI), polyethylene napthalate (PEN), polyethylene terephthalate (PET), polyphenylene sulfonate (PPS), polyallylate, polyimide (PI), polycarbonate (PC), cellulose triacetate (CAT), cellulose acetate propionate (CAP), or a combination thereof. Alternatively, the substrate SUB may include a metal material.

The substrate SUB may be a rigid substrate or a flexible substrate capable of bending, folding, rolling, etc. If the substrate SUB is a flexible substrate, it may be formed of polyimide (PI) but is not limited thereto.

The thin film transistor layer TFTL may be located on the substrate SUB. The thin film transistor layerTFTL may include thin film transistors for each of the pixels, as well as scan lines, data lines, power supply lines, scan control lines, and routing lines connecting the pads and data lines. Each of the thin film transistors may include a gate electrode, a semiconductor layer, a source electrode, and a drain electrode.

The thin film transistor layer TFTL may be located in the display area DA and the non-display area NDA. For example, thin film transistors, scan lines, data lines, and power supply lines of each pixel of the thin film transistor layer TFTL may be located in the display area DA. The scan control lines and link lines of the thin film transistor layer TFTL may be located in the non-display area NDA.

The light emitting element layer EML may be located on the thin film transistor layer TFTL. The light emitting element layer EML may include pixels including a first electrode, a light emitting layer, and a second electrode, and a pixel defining layer defining the pixels. The light emitting layer may be an organic light emitting layer including an organic material. In this case, the light emitting layer may include a hole transporting layer, an organic light emitting layer, and an electron transporting layer. When a voltage (e.g., a set or predetermined voltage) is applied to the first electrode through the thin film transistor of the thin film transistor layer TFTL and a cathode voltage is applied to the second electrode, holes and electrons are moved to the organic light emitting layer through the hole transport layer and electron transport layer, respectively. They combine with each other in the light emitting layer and emit light. The pixels of the light emitting element layer EML may be located in the display area DA.

The thin film encapsulation layer TFEL may be located on the light emitting element layer EML. The thin film encapsulation layer TFEL serves to prevent or reduce instances of oxygen, moisture, or other contaminants penetrating into the light emitting element layer EML. For this purpose, the thin film encapsulation layer TFEL may include at least one inorganic layer. The inorganic film may be a silicon nitride layer, a silicon oxy nitride layer, a silicon oxide layer, a titanium oxide layer, or an aluminum oxide layer but is not limited thereto. In addition, the thin film encapsulation layer TFEL serves to protect the light emitting element layer EML from foreign substances such as dust. To this end, the thin film encapsulation layer TFEL may include at least one organic layer. The organic layer may be acryl resin, epoxy resin, phenolic resin, polyamide resin, or polyimide resin but embodiments according to the present disclosure are not limited thereto.

The thin film encapsulation layer TFEL may be located in both the display area DA and the non-display area NDA. For example, the thin film encapsulation layer TFEL may be arranged to cover the light emitting element layer EML in the display area DA and the non-display area NDA and to cover the thin film transistor layer TFTL in the non-display area NDA.

A cover window may be further located on the thin film encapsulation layer TFEL, and a touch sensing layer may be further located between the thin film encapsulation layer TFEL and the cover window. In this case, the cover window may be attached to the lower layer by a transparent adhesive member such as an optically clear adhesive (OCA) film.

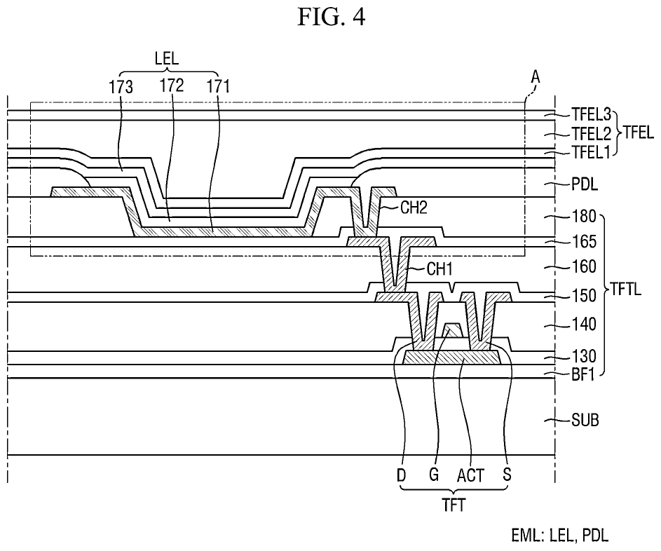

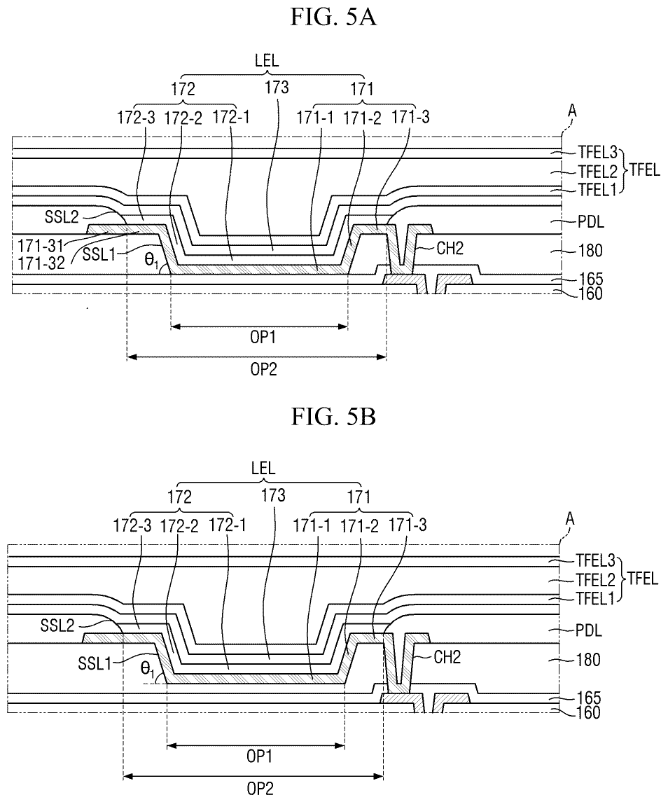

FIG. 4 is a cross-sectional view illustrating one example of a structure of a sub-pixel included in a display device according to some embodiments of the present disclosure. FIGS. 5A and 5B are cross-sectional views illustrating one example of an enlarged view of area A of FIG. 4.

The pixel PX may include a plurality of light emitting elements LE and may be defined as the minimum light emitting unit capable of displaying white light by combining light emitted by the plurality of light emitting elements LE.

The pixel PX may include a plurality of sub-pixels. Each of the plurality of sub-pixels PX may display light of different wavelengths.

Referring to FIGS. 4 and 5A, a thin film transistor layer TFTL is formed on the substrate SUB of the display device 10. The thin film transistor layer TFTL includes thin film transistors TFT, a gate insulating layer 130, an interlayer insulating layer 140, a first protective layer 150, a planarization layer 160, and a via layer 180.

A buffer layer BF1 may be further formed on one surface of the substrate SUB. The buffer layer BF1 may be formed on one side of the substrate SUB to protect the thin film transistors TFT and an organic light emitting layer 172 of the light emitting element layer EML from moisture penetrating through the substrate SUB, which is vulnerable to moisture permeation. The buffer layer BF1 may include a plurality of inorganic films alternately stacked. For example, the buffer layer BF1 may be formed as a plurality of alternately stacked inorganic films of one or more of a silicon nitride layer, a silicon oxynitride layer, a silicon oxide layer, a titanium oxide layer, and an aluminium oxide layer. The buffer layer BF1 may be omitted.

The thin film transistor TFT is formed on the buffer layer BF1. The thin film transistor TFT includes an active layer ACT, a gate electrode G, a source electrode S, and a drain electrode D. In FIG. 4, the thin film transistor TFT is illustrated in a top gate (top gate) manner in which the gate electrode G is located on top of the active layer ACT, but it should be noted that the TFT is not limited to this. In other words, thin film transistors TFT may be formed in a bottom gate manner in which the gate electrode G is located at the bottom of the active layer ACT or in a double gate manner in which the gate electrode G is located at both the top and bottom of the active layer ACT.

The active layer ACT is formed on the buffer layer BF1. The active layer ACT may include polycrystalline silicon, single crystalline silicon, low-temperature polycrystalline silicon, amorphous silicon, or an oxide semiconductor. For example, oxide semiconductors may include a binary compound (Abx), a ternary compound (AbxCy), or a tetracyclic compound (AbxCyDz) containing indium, zinc, gallium, tin, titanium, aluminium, hafnium (Hf), zirconium (Zr), magnesium (Mg), and the like. For example, the active layer ACT may IIe ITZO (an oxide containing indium, tin, and titanium) or IGZO (an oxide containing indium, gallium, and tin). A light blocking layer may be formed between the buffer layer and the active layer ACT to block external light incident on the active layer ACT.

The gate insulating layer 130 may be formed on the active layer ACT. The gate insulating layer 130 may be formed of an inorganic layer, such as a silicon nitride layer, a silicon oxynitride layer, a silicon oxide layer, a titanium oxide layer, or an aluminium oxide layer.

The gate electrode G and a gate line may be formed on the gate insulating layer 130. The gate electrode G and the gate line may be formed as a single layer or multiple layers of any one of molybdenum (Mo), aluminium (Al), chromium (Cr), gold (Au), titanium (Ti), nickel (Ni), neodymium (Nd), and copper (Cu), or an alloy thereof.

The interlayer insulating layer 140 may be formed on the gate electrode G and the gate line. The interlayer insulating layer 140 may be formed of an inorganic layer, such as a silicon nitride layer, a silicon oxynitride layer, a silicon oxide layer, a titanium oxide layer, or an aluminium oxide layer.

The source electrode S and the drain electrode D may be formed on the interlayer insulating layer 140. Each of the source electrode S and the drain electrode D may be connected to the active layer ACT through a contact hole penetrating the gate insulating layer 130 and the interlayer insulating layer 140. The source electrode S and drain electrode D may be formed as a single layer or multiple layers of any one of molybdenum (Mo), aluminium (Al), chromium (Cr), gold (Au), titanium (Ti), nickel (Ni), neodymium (Nd), and copper (Cu), or an alloy thereof.

The first protective layer 150 may be formed on the source electrode S and the drain electrode D to insulate the thin film transistor TFT. The first protective layer 150 may be formed of an inorganic layer, such as a silicon nitride layer, a silicon oxynitride layer, a silicon oxide layer, a titanium oxide layer, or an aluminium oxide layer.

The planarization layer 160 may be formed on the first protective layer 150 to flatten the step caused by the thin film transistor TFT.

A first contact hole CH1 may be formed in the planarization layer 160. The first contact hole CH1 may be formed to expose the drain electrode D of the thin film transistor TFT. A second contact hole CH2 may be formed in the via layer 180. The second contact hole CH2 may be formed to expose the first contact hole CH1. Accordingly, a first electrode 171 may be connected to the drain electrode D of the thin film transistor TFT through the second contact hole CH2 and the first contact hole CH1.

The planarization layer 160 may be”form'd of an organic film such as acrylic resin, epoxy resin, phenolic resin, polyamide resin, polyimide resin, or the like.

A second protective layer 165 may be formed on the planarization layer 160. The second protective layer 165 may be formed of an inorganic layer, for example, such as a silicon nitride layer, a silicon oxynitride layer, a silicon oxide layer, a titanium oxide layer, or an aluminium oxide layer. The second protective layer 165 may be omitted. The via layer 180 may be located on the second protective layer 165. The via layer 180 may be formed of an organic material, for example, an acrylic resin, an epoxy resin, a phenolic resin, a polyamide resin, a polyimide resin, or the like.

The via layer 180 may include a sloped surface SSL1 defining a recess OP1. Further, the sloped surface SSL1 of the via layer 180 may have a gentle slope with respect to the top surface of the substrate SUB. The first spacing angle θ1 formed by the sloped surface SSL1 of the via layer 180 and the downward extension of the recess OP1 may be an acute angle. For example, the first spacing angle θ1 may be about 10 degrees to 40 degrees. The first electrode 171 may be located on the sloped surface SSL1 of the via layer 180. The recess OP1 may be a through-hole through which the the planarization layer 160 is exposed, the recess OP1 may be a layer located below the via layer 180, for example, the second protective layer 165 or when the second protective layer 165 is omitted as shown in FIG. 5A. However, embodiments according to the present disclosure are not limited thereto. The recess OP1 may be a recess shaped to be concave from the top to the bottom of the via layer 180, as shown in FIG. 5B.

In addition, while the via layer 180 is illustrated as a single layer in FIGS. 5A and 5B, it may be formed by laminating two or more layers. For example, the via layer 180 includes a first via layer and a second via layer, and the first via layer may be formed on the second via layer.

The light emitting element layer EML may be located on the thin film transistor layer TFTL. The light emitting element layer EML may include light emitting elements LEL and a pixel defining layer PDL.

Each of the light emitting elements LEL may include the first electrode 171, the organic light emitting layer 172, and a second electrode 173.

The first electrode 171 may be located in the recess OP1 of the via layer 180 and may extend along the sloped surface SSL1 of the via layer 180.

The first electrode 171 may include an in inclined electrode 171-2 located along the sloped surface SSL1 of the via layer 180. Also, the first electrode 171 may further include a lower electrode 171-1 extending from the bottom of the inclined electrode 171-2 and located within the recess OP1, and an upper electrode 171-3 extending from the top of the inclined electrode 171-2 and located on the top surface of the via layer 180.

The upper electrode 171-3 may be at least partially covered by a pixel defining layer PDL. The upper electrode 171-3 may include a concealed portion 171-31 covered by the pixel defining layer PDL and an exposed portion 171-32 not covered by the pixel defining layer PDL. The concealed portion 171-31 overlaps the pixel defining layer PDL, and the exposed portion 171-32 does not overlap the pixel defining layer PDL.

The exposed portion 171-32 can be viewed as a margin area taking into account the scattering of the pixel defining layer PDL. The exposed portion 171-32 may have a length of 1 micrometers (μm) to 2 μm (or about 1 μm to 2 μm).

By securing the margin area, the pixel defining layer PDL may not cover the inclined electrodes 171-2 in the event of misalignment of the pixel defining layer PDL.

According to some embodiments, the first electrode 171 may be an anode electrode. If the first electrode 171 is the anode electrode, the first electrode 171 may include a reflective material. The reflective material may include, according to some embodiments, one or more reflectors selected from the group consisting of silver (Ag), magnesium (Mg), chromium (Cr), gold (Au), platinum (Pt), nickel (Ni), copper (Cu), tungsten (W), and aluminium (Al), and a transparent or translucent electrode formed on the reflector.

Here, the transparent or translucen”t el'ctrode may include one or more selected from the group consisting of indium tin oxide (ITO), indium zinc oxide (IZO), zinc oxide (ZnO), indium oxide (In₂O₃), indium gallium oxide (IGO), and aluminium zinc oxide (AZO).

The pixel defining layer PDL may be formed to compartmentalize the first electrode 171. The pixel defining layer PDL may be formed to cover the edge of the first electrode 171. The pixel defining layer PDL may be formed of an organic film such as acryl resin, epoxy resin, phenolic resin, polyamide resin, or polyimide resin.

The pixel defining layer PDL may include a sloped surface SSL2 defining a second opening OP2.

The width of the second opening OP2 defined by the pixel defining layer PDL may be wider than the width of the recess OP1 defined by the via layer 180. In this case, the width of the recess OP1 may be defined as the shortest distance between the sloped surface SSL1 of the via layer 180, and the width of the second opening OP2 may be defined as the shortest distance between the sloped surface SSL2 of the pixel defining layer PDL.

The sloped surface SSL2 of the pixel defining layer PDL may have a gentle slope with respect to the top surface of the via layer VIA.

Each of the sub-pixels represents a region where the first electrode 171, the organic light emitting layer 172, and the second electrode 173 are sequentially stacked so that holes from the first electrode 171 and electrons from the second electrode 173 are combined with each other in the organic light emitting layer 172 to emit light. Each sub-pixel may include a light emitting element LEL.

The organic light emitting layer 172 is formed on the first electrode 171.

The organic light emitting layer 172 may include an organic material and may emit a color (e.g., a set or predetermined color). For example, the organic light emitting layer 172 may include a hole transporting layer, an organic material layer, and an electron transporting layer. For example, the organic light emitting layer 172 of the first sub-pixel may emit light of a first color, the organic light emitting layer 172 of the second sub-pixel may emit light of a second color, and the organic light emitting layer 172 of the third sub-pixel may emit light of a third color. The first color may be red, the second color may be green, and the third color may be blue, but embodiments according to the present disclosure are limited thereto.

Alternatively, the organic light emitting layer 172 of each sub-pixel may emit white light. For example, the first sub-pixel may overlap with a color filter layer of the first color, the second sub-pixel may overlap with a color filter layer of the second color, and the third sub-pixel may overlap with a color filter layer of the third color.

The organic light emitting layer 172 may be arranged to overlap the lower electrode 171-1, the inclined electrode 171-2, and the upper electrode 171-3 of the first electrode 171. The organic light emitting layer 172 may include a first flat portion 172-1, an inclined portion 172-2, and a second flat portion 172-3. The first flat portion 172-1 is located on the lower electrode 171-1 of the first electrode 171, the inclined portion 172-2 is located on the inclined electrode 171-2 of the first electrode 171, and the second flat portion 172-3 is located on the upper electrode 171-3 of the first electrode 171. Accordingly, the first flat portion 172-1 may overlap the recess OP1 of the via layer 180, the inclined portion 172-2 may overlap the sloped surface SSL1 of the via layer 180, and the second flat portion 172-3 may overlap the top of the via layer 180. According to some embodiments, the first flat portion 172-1 and the second flat portion 172-3 are named as flat but may be formed to have a curvature during the process. Even in this case, the first flat portion 172-1 and the second flat portion 172-3 may be formed to be relatively flat compared to the inclined portion 172-2.

Among the light emitted from the organic light emitting layer 172, the light that is not emitted from the top surface of the organic light emitting layer 172 and travels to the side of the first electrode 171 is reflected by the inclined electrode 171-2 of the first electrode 171 so that it may proceed to the top surface of the organic light emitting layer 172. In other words, the inclined electrode 171-2 of the first electrode 171 may guide the side light of the organic light emitting layer 172 to proceed to the top surface without being lost, thereby relatively improving the light extraction efficiency and providing a high luminous efficiency. In addition, the inclined electrode 171-2 of the first electrode 171 affects the improvement of the white angular dependency (WAD) phenomenon in which the color shifts to blue due to a white-out phenomenon on the side. In this way, the inclined electrode 171-2 of the first electrode 171 has a direct effect on improving reflectivity and WAD.

According to some embodiments, the organic light emitting layer 172 may emit one of red light, green light, and blue light. The wavelength of red light may be about 620 nm to 750 nm, and the wavelength of green light may be about 495 nm to 570 nm. Additionally, the wavelength of blue light may be about 450 nm to 495 nm.

In another example, the organic light emitting layer 172 may emit white light. When the organic light emitting layer 172 emits white light, the organic light emitting layer 172 may have a stacked form of a red light emitting layer, a green light emitting layer, and a blue light emitting layer according to some embodiments. Additionally, it may further include a separate color filter for displaying red, green, and blue.

According to some embodiments, the organic light emitting layer 172 may be a multi-layer structure including a hole transporting layer, an organic light emitting layer, and an electron transporting layer.

The second electrode 173 is formed on the organic light emitting layer 172 and the pixel defining layer PDL. The second electrode 173 may be formed to cover the organic light emitting layer 172 and the pixel defining layer PDL. The second electrode 173 may be a common layer commonly formed in all light emitting elements LEL. The second electrode 173 may be a cathode electrode according to some embodiments. The second electrode 173 may include one or more elements selected from the group consisting of Li. Ca, LiF/Ca, LiF/Al, Al, Ag, and Mg according to some embodiments. Additionally, the second electrode 173 may be made of a thin metal film with a low work function. The second electrode 173 may be a transparent or translucent electrode including one or more selected from the group consisting of indium tin oxide (ITO), indium zinc oxide (IZO), zinc oxide (ZnO), indium oxide (In₂O₃), indium gallium oxide (IGO), and aluminium zinc oxide (AZO) according to some embodiments.

In the upper light emitting structure, the second electrode 173 may be formed of a transparent conductive oxide (TCO), such as indium tin oxide (ITO) and indium zinc oxide (IZO), which may transmit light, or a semi-transmissive conductive material, such as magnesium (Mg), silver (Ag), or an alloy of magnesium (Mg) and silver (Ag). If the second electrode 173 is formed of the semi-transmissive conductive material, the light emission efficiency may be increased due to a micro cavity. A capping layer may be formed on the second electrode 173.

An encapsulation layer TFEL may be located on the second electrode 173. The encapsulation layer TFEL is located on the second electrode 173. The encapsulation layer TFEL may include at least one inorganic layer to prevent or reduce instances of oxygen, moisture, or other contaminants penetrating into the organic light emitting layer 172 and the second electrode 173. Additionally, the encapsulation layer TFEL may include at least one organic layer to protect the light emitting element layer EML from foreign substances such as dust. For example, the encapsulation layer TFEL may include a first inorganic film TFE1 located on the second electrode 173, an organic film TFE2 located on the first inorganic film TFE1, and a second inorganic film TFE3 located on the organic film TFE2. The first inorganic layer TFE1 and the second inorganic layer TFE3 may be formed of a silicon nitride layer, a silicon oxynitride layer, a silicon oxide layer, a titanium oxide layer, or an aluminium oxide layer, but embodiments according to the present disclosure are not limited thereto. The organic film may be formed of acryl resin, epoxy resin, phenolic resin, polyamide resin, polyimide resin, and the like, but embodiments according to the present disclosure are not limited thereto.

A second buffer layer may be formed on the thin film encapsulation layer TFEL. The second buffer layer may be composed of a plurality of inorganic films alternately stacked. For example, the second buffer layer may be formed as a plurality of alternately stacked inorganic films of one or more of a silicon nitride layer, a silicon oxynitride layer, a silicon oxide layer, a titanium oxide layer, and an aluminium oxide layer. The second buffer layer may be omitted.

Each pixel area PA of the display panel DP may include a light emitting area PXA and a non-emitting area NPXA. The light emitting area PXA is an area of each pixel area PA where the organic light emitting layer 172 that emits actual light is located, and the non-emitting area NPXA may be a light blocking area adjacent to the light emitting area PXA and where a light blocking material such as a black matrix is located. According to some embodiments, the light emitting area PXA may be formed wider than the second opening OP2 defined by the pixel defining layer PDL.

A plurality of micro lenses MLA may be located on the thin film encapsulation layer TFEL. Each of the plurality of micro lenses MLA may be arranged to overlap the light-emitting area PXA of the corresponding pixel area PA.

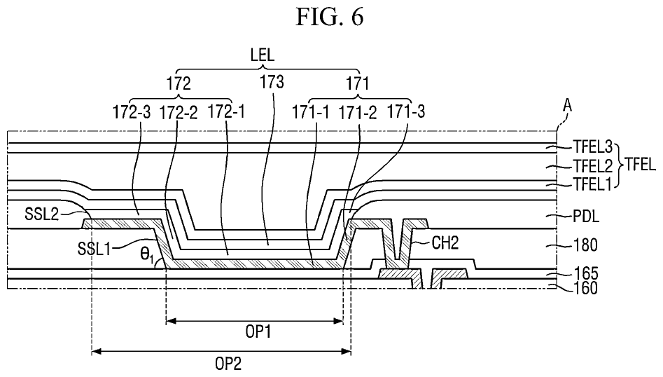

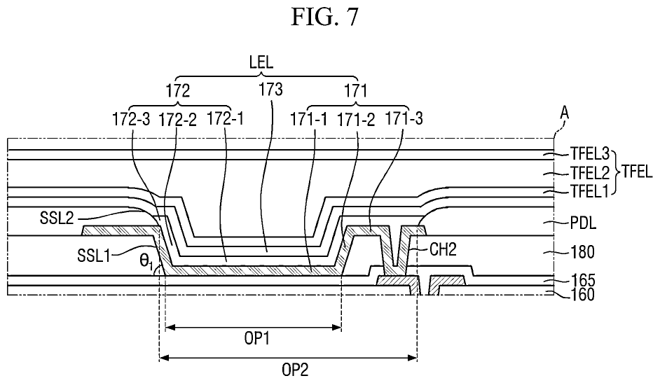

FIGS. 6 and 7 are cross-sectional views of a light emitting element and a pixel definition layer to illustrate alignment of the pixel definition layer.

Referring to FIG. 6, the pixel defining layer PDL may be pushed to one side in the first direction, or referring to FIG. 7, the pixel defining layer PDL may be pushed to the other side in the first direction.

If the pixel defining layer PDL is misaligned as shown in FIGS. 6 and 7, it may cover at least a portion of the exposed portion 171-32. Even when the pixel defining layer PDL is misaligned in this way, the inclined electrode 171-2 may still be exposed by the pixel defining layer PDL. Thus, screen smudges and the like that may be caused by the overlap of the pixel defining layer PDL with the inclined electrodes 171-2 may be prevented or reduced.

Hereinafter, the alignment mark will be described in more detail.

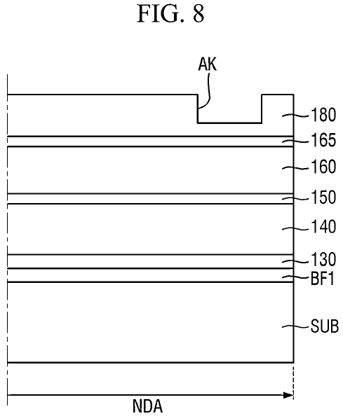

FIG. 8 is a schematic cross-sectional view of the structure of an alignment mark AK area.

The alignment mark AK of the display device 10 according to some embodiments of the present disclosure shown in FIG. 8 are of a configuration corresponding to the alignment marks AK of the display device 10 shown in FIG. 2. The alignment mark AK may be made of the same organic material as the via layer 180.

Referring to FIG. 8, the substrate SUB, the gate insulating layer 130, the interlayer insulating layer 140, the first protective layer 150, the planarization layer 160, and the via layer 180 may be stacked and arranged sequentially in the non-display area NDA of the display device 10. The substrate SUB, the gate insulating layer 130, the interlayer insulating layer 140, the first protective layer 150, the planarization layer 160, and the second protective layer 165 have been described with reference to FIGS. 4 and 5A, a redundant description will be omitted.

The buffer layer BF1, the interlayer insulating layer 140, and the planarization layer 160 may further include alignment marks formed of metal.

The via layer 180 may include an alignment mark AK formed in an engraved pattern in which a portion of the top surface of the via layer 180 is recessed.

The alignment mark AK may be formed by patterning the via layer 180. The alignment mark AK may include an ink that fills the engraved pattern, and the ink may have a different color than the top surface of the via layer 180. The ink may be omitted.

The pixel defining layer PDL may be formed based on the alignment mark AK of the via layer 180.

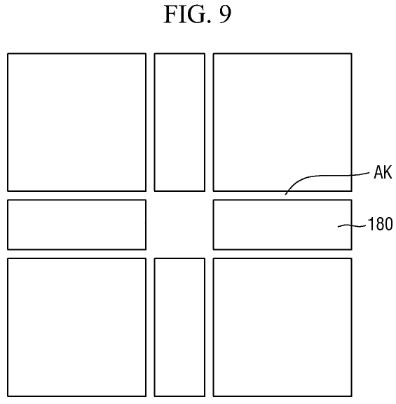

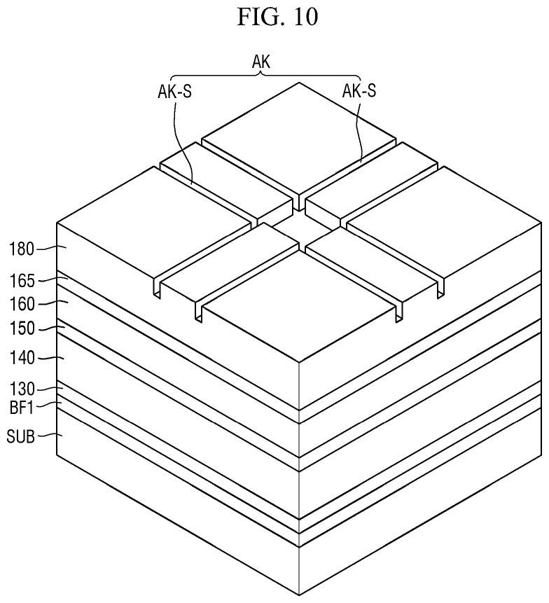

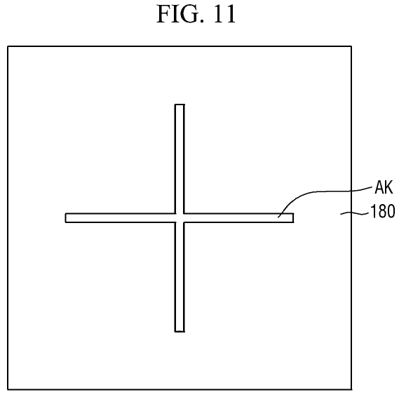

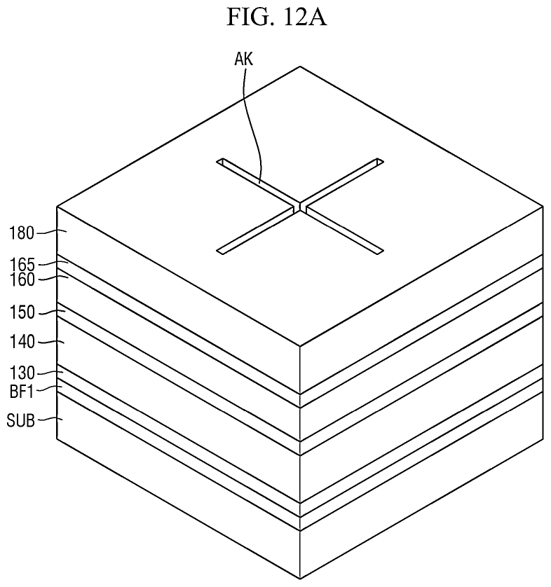

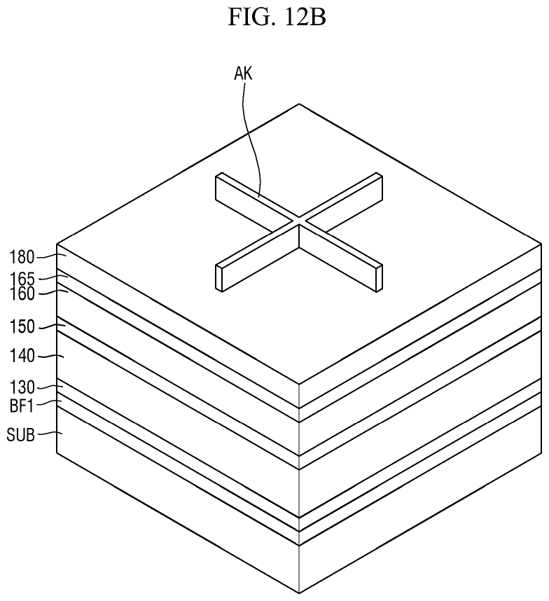

FIG. 9 is a plan view to illustrate the alignment mark of FIG. 8, according to some embodiments of the present disclosure. FIG. 10 is a schematic diagram to illustrate the alignment mark of FIG. 9. FIG. 11 is a plan view to illustrate the alignment marks according to some embodiments of the present disclosure. FIGS. 12A and 12B are schematic diagrams to illustrate the alignment mark of FIG. 11.

As shown in FIG. 9, the pattern of the alignment mark AK may be in the shape of a cross (+). As shown in FIG. 10, a cross-shaped alignment mark AK pattern may be engraved.

In addition to the pattern of alignment mark illustrated in FIG. 9, the pattern of alignment mark may have various planar shapes. For example, the alignment mark AK may have a planar shape such as a straight line, a square, a triangle, a hexagon, a circle, or the like.

As shown in FIGS. 11, 12A, and 12B, the pattern of the alignment mark AK may be composed of a plurality of sub-patterns AK-S, and the shape of each sub-pattern AK-S may be the same or different. Although the alignment mark AK is shown as including four ‘L’ shaped sub-patterns AK-S, it is not limited thereto.

The alignment mark AK may be formed in an engraved pattern as shown in FIG. 12A or in an embossed pattern as shown in FIG. 12B.

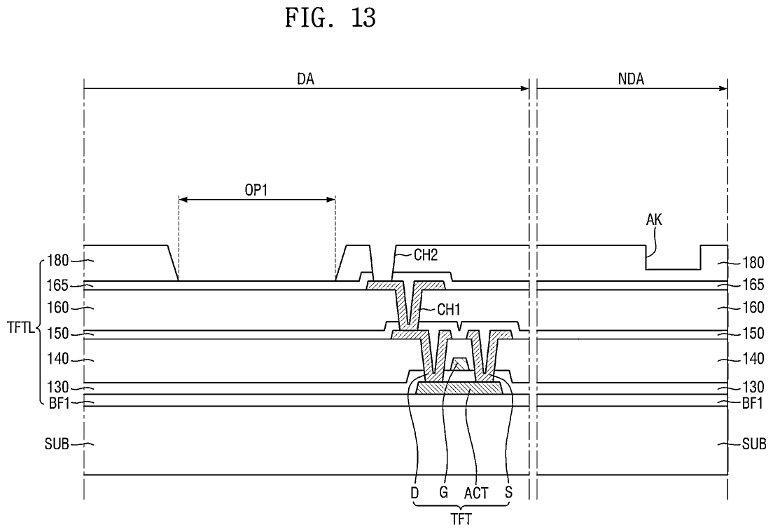

The manufacturing method of the display device described above will be described with reference to FIGS. 13 to 16.

FIGS. 13 to 17 are process flowcharts for manufacturing a display device. The following process sequence is merely explanatory of aspects of some embodiments and does not limit the disclosure. Additionally, although aspects of various operations or processing sequences are illustrated, embodiments according to the present disclosure may include additional operations or processing sequences without departing from the spirit and scope of embodiments according to the present disclosure. It will be described with reference to FIGS. 4 and 8.

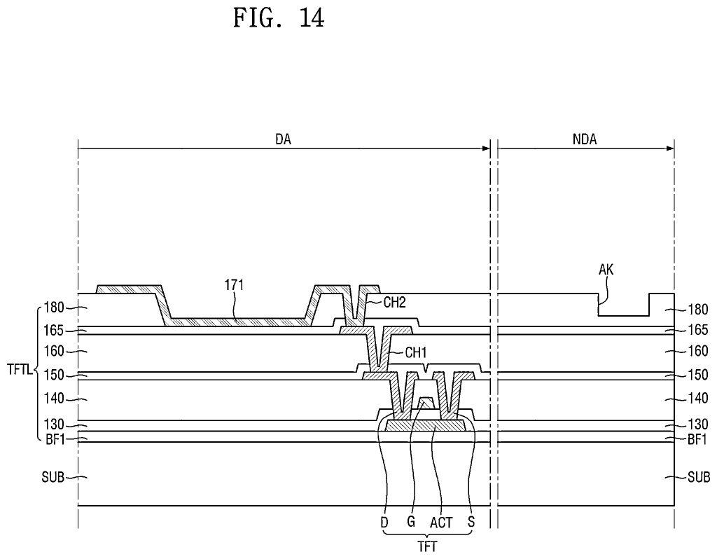

In FIG. 14, the display area may correspond to the display area described with reference to FIGS. 4, 5A, and 5B, and the non-display area may correspond to the non-display area described with reference to FIG. 8. Referring to FIG. 13, a substrate SUB on which a thin film transistor TFT is formed may be prepared. A first protective layer 150 and a planarization layer 160 may be further located on the substrate SUB on which the thin film transistor TFT is formed.

An organic layer is formed on the planarization layer 160 and patterned to form a recess OP1 and an alignment mark AK on the via layer 180. To form the via layer 180, the organic layer is first stacked on the planarization layer 160 in various ways, and the recess OP1 and alignment mark AK are patterned using a photolithographic process using a first mask and an etching process to form the via layer 180. The recess OP1 may be patterned to be convex downward toward the bottom surface of the via layer 180. In this way, the alignment mark AK may be formed by the recess OP1 formed in the via layer 180. The buffer material may include organic materials such as acryl resin, epoxy resin, phenolic resin, polyamide resin, polyimide resin, and the like.

Next, referring to FIG. 14, the first electrode 171 may be formed on the via layer 180. For example, a conductive material layer may be deposited on the via layer 180. The conductive material layer may include, for example, one or more selected from the group consisting of indium tin oxide (ITO), indium zinc oxide (IZO), zinc oxide (ZnO), indium oxide (In₂O₃), indium gallium oxide (IGO), and aluminium zinc oxide (AZO). The conductive material layer may be patterned into the first electrode 171 using a photolithographic process and an etching process using a second mask.

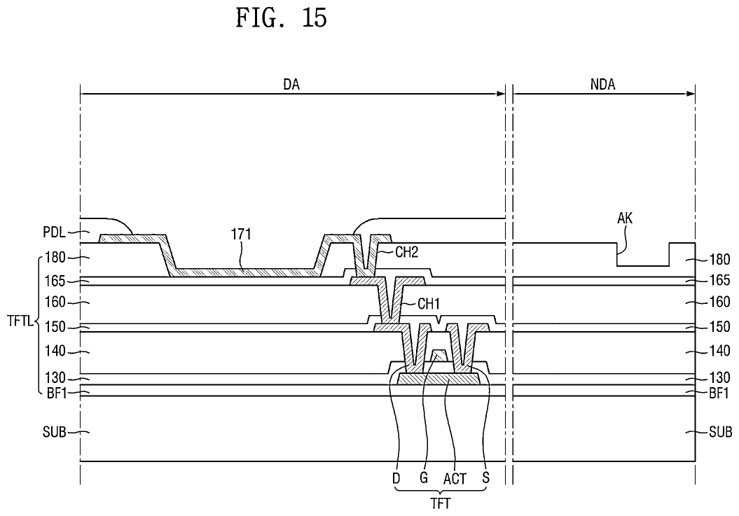

Next, referring to FIG. 15, a pixel defining layer PDL is formed on the via layer 180 and the first electrode 171 using the alignment mark AK. The pixel defining layer PDL may be formed by methods such as spin coating with one or more organic insulating materials selected from the group consisting of acrylic resin, epoxy resin, phenolic resin, polyamide resin, and polyimide resin. The pixel defining layer PDL may be patterned to expose at least a portion of the top surface of the first electrode 171 through a photolithography process and an etching process using a third mask. When forming the pixel definition layer PDL, the formation position of the pixel definition layer PDL may be confirmed by recognizing the alignment mark AK in the non-display area NDA.

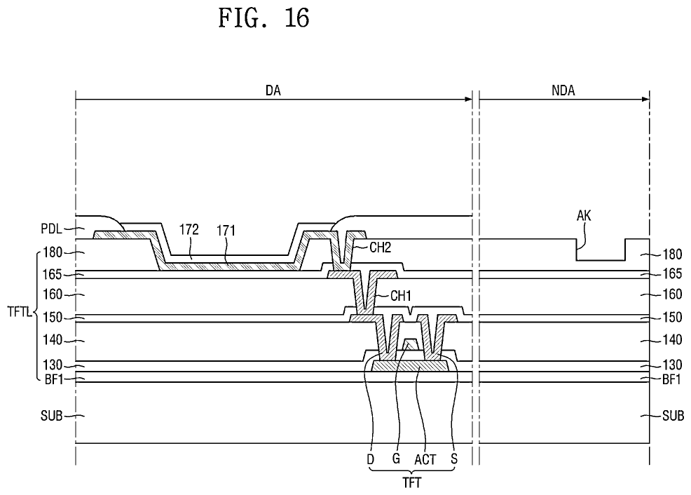

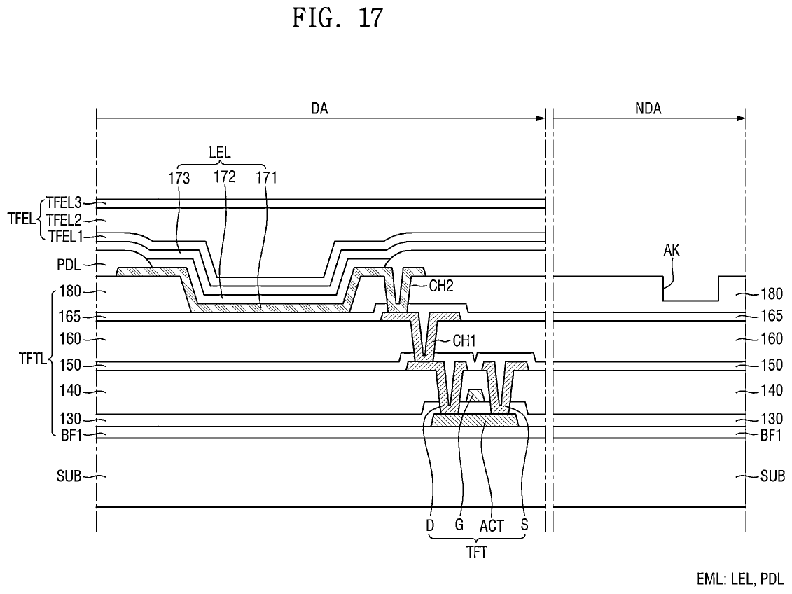

Referring to FIG. 16, an organic light emitting layer 172 may be formed on the first electrode 171. The alignment mark AK may be used to align the organic light emitting layer 172. The organic material deposition device may recognize the aligned alignment mark to obtain a position of the pixel electrode and deposit organic matter on the pixel electrode to form the organic light emitting layer 172. In addition to the organic emissive layer (EML), the organic light emitting layer 172 may be formed by stacking one or more of the following functional layers: a hole transport layer (HTL), a hole injection layer (HIL), an electron transport layer (ETL), and an electron injection layer (EIL) into a single or composite structure. The organic light emitting layer 172 may be made of a low-molecular or high-molecular organic material.

Next, referring to FIG. 17, a second electrode 173 may be formed on the organic light emitting layer 172, and then an encapsulation layer TFEL may be formed on the second electrode 173.

The second electrode 173 may be formed on the display area DA of the display panel 100. The second electrode 173 may be formed on the entire surface of the display area DA.

The encapsulation layer TFEL may be attached to the display panel 100. The encapsulation layer TFEL may be bonded to the substrate using a sealing member.

However, the features of embodiments according to the present disclosure are not restricted to the one set forth herein. The above and other features of embodiments according to the present disclosure will become more apparent to one of ordinary skill in the art to which the disclosure pertains by referencing the claims, with functional equivalents thereof to be included therein.

What is claimed is:

1. A display device comprising:
a substrate including a display area and a non-display area;
a thin film transistor on the substrate;
a planarization layer on the thin film transistor;
a via layer on the planarization layer, having a recess in the display area and an alignment mark in the non-display area;
a sub-pixel including a first electrode, an organic light emitting layer, and a second electrode corresponding to the recess; and
a pixel definition layer defining the sub-pixel on the via layer,
wherein the first electrode is electrically connected to the thin film transistor and includes an inclined electrode arranged along a sloped surface of the recess.

2. The display device of claim 1, wherein the first electrode further comprises a lower electrode extending from a bottom end of the inclined electrode and in the recess, and an upper electrode extending from a top end of the inclined electrode and on a top surface of the via layer.

3. The display device of claim 2, wherein the upper electrode comprises a concealed portion that overlaps the pixel defining layer and an exposed portion that does not overlap the pixel defining layer.

4. The display device of claim 3, wherein the exposed portion has a length in a range of 1 micrometers (μm) to 2 μm.

5. The display device of claim 2, wherein the organic light emitting layer overlaps the lower electrode, the inclined electrode, and the upper electrode.

6. The display device of claim 1, wherein the pixel defining layer directly contacts a top surface of the via layer.

7. The display device of claim 1, wherein the alignment mark is made of a same material as the via layer.

8. The display device of claim 1, wherein the alignment mark is formed in an engraved pattern in which a portion of a top surface of the via layer is recessed.

9. The display device of claim 8, wherein the alignment mark comprises an ink that fills the engraved pattern, and the ink has a different color to the top surface of the via layer.

10. The display device of claim 1, further comprising a thin film encapsulation layer on the sub-pixel and the pixel defining layer.

11. A method of manufacturing display device comprising:
forming a planarization layer on a substrate having a thin film transistor;
forming an organic layer on the planarization layer;
patterning the organic layer to form a via layer having a recess and an alignment mark;
forming a first electrode electrically connected to the thin film transistor and including an inclined electrode arranged along a sloped surface of the recess; and
forming a pixel defining layer exposing at least a portion of the first electrode on the via layer using the alignment mark.

12. The method of claim 11, further comprising:
forming a lower electrode extending from a bottom end of the inclined electrode and in the recess, and an upper electrode extending from a top end of the inclined electrode and on a top surface of the via layer in forming the first electrode.

13. The method of claim 11, further comprising:
forming an organic light emitting layer on a first electrode exposed by the pixel defining layer; and
forming a second electrode on the organic light emitting layer.

14. The method of claim 12, wherein the pixel defining layer exposes the lower electrode and the inclined electrode and overlaps at least a portion of the upper electrode.

15. The method of claim 14, wherein the upper electrode comprises a concealed portion that overlaps the pixel defining layer and an exposed portion that does not overlap the pixel defining layer,
wherein the exposed portion has a length in a range of 1 micrometers (μm) to 2 μm.

16. The method of claim 11, wherein the pixel defining layer is formed to be in direct contact with a top surface of the via layer.

17. The method of claim 11, wherein the alignment mark is made of a same material as the via layer.

18. The method of claim 11, wherein the alignment mark is formed in an engraved pattern in which a portion of the top surface of the via layer is recessed.

19. The method of claim 18, wherein the alignment mark comprises an ink that fills the engraved pattern,
wherein the ink has a different color to the top surface of the via layer.

20. The method of claim 13, further comprising forming a thin film encapsulation layer on the second electrode.
